(19) United States
(12) Patent Application Publication
(10) Pub. No.: US 2010/0220019 A1
(43) Pub. Date: Sep. 2, 2010

(54) GLAZING

(75) Inventor: Joseph Jeremy Boote, Lathom (GB)

Correspondence Address: BUCHANAN, INGERSOLL & ROONEY PC, POST OFFICE BOX 1404, ALEXANDRIA, VA, 22313-1404, US

(73) Assignee: PILKINGTON GROUP LIMITED, St. Helens (GB)

(21) Appl. No.: 12/682,750

(22) PCT Filed: Oct. 17, 2008
(86) PCT No.: PCT/GB2008/050954

§ 371 Date: Apr. 12, 2010

(30) Foreign Application Priority Data
Oct. 17, 2007 (GB) 0720268.2

(51) Int. Cl. H01Q 1/32; H01Q 1/00; G01R 27/26; H05K 1/00; H05K 1/16

(52) U.S. Cl. 343/713; 343/720; 324/658; 361/748; 174/260

(57) ABSTRACT

A glazing comprising a pane of glazing material, and a substantially continuous area of transparent, electrically conductive material printed using an electrically conductive ink onto a surface of the pane, wherein the ink is of a composition comprising a fluid vehicle (e.g. a solvent) and two different metal species (e.g. tin and indium), said fluid vehicle being driven off in a high-temperature post-printing step, and the conductive material is capable of functioning as one or more of the following: (a) a heating element for heating an area of the glazing; (b) an alarm sensor for detecting when the structural integrity of the glazing has been compromised; (c) a capacitive proximity sensor for detecting an approach to, or contact with, a surface of the glazing; (d) an electrical connection to an electrical device associated with the glazing; (e) an antenna for receiving and/or transmitting electromagnetic radiation. The glazing may also be a laminate.

The present invention relates to a glazing which has an area of transparent, electrically conductive material printed on one of its surfaces.

It is well known to provide a glazing with a functional element that requires an electrical connection in order to perform its function. Examples of such functional elements include heating elements, alarm sensors, integrated lighting sources, capacitive touch sensors, rain sensors, to name but a few. Accordingly it is known to provide a glazing with a means of electrical conductivity for supply of an electrical current to the functional element. Sometimes it may be possible to provide a functional element and its means of electrical conductivity integrally from the same material.

The types of material typically used in the manufacture of prior art electrically conductive glazings include fine metallic wires (often copper wires of diameter less than 50 μm), transparent electrically conductive coatings (for example sputtered silver-based coatings) and silver ink Fine wires are commonly used to create antenna lines and heating arrays by embedding the wires into a flexible substrate which forms a part of a glazing. Silver ink may be screen-printed onto a surface of a pane of glazing material comprised in a glazing to create alarm sensors and antenna lines. Coatings may be provided on a surface of a pane of glazing material or on a flexible substrate to create heating areas, capacitive sensor pads/lines, antenna lines and electrical pathways for other functional elements.

Although each of these materials performs adequately, each has its disadvantageous features. Despite their small diameter, and even when darkened to reduce their visibility, fine wires may remain visible to the naked eye when incorporated in a glazing and can affect the optics of the glazing. Silver ink is of course highly visible and usually requires concealment by an over-print of, for example a black ink, to improve the aesthetics of the glazing. Coatings which may initially appear transparent may also induce optical distortion in a glazing, especially when a boundary of a coated area is located in a major vision area of a glazing, as the difference in transparency between the coated area and the uncoated area may be enhanced. Coatings have a further disadvantage: in creation of a patterned coated area, or numerous coated areas in close proximity, a larger area coating may be deposited and subsequently laser-deleted in certain areas to achieve the desired finish. Such an approach may lead to significant wastage of the coating material, which may equate to significant monetary loss. However this approach may still be preferable to the alternative of masking an area prior to coating deposition as the desired accuracy in detail may not be achievable this way.

The aforesaid disadvantages are especially significant when the glazing is used as a window in a building or an automotive window, where the aesthetics and optics are of paramount importance.

It is therefore an object of the present invention to provide an electrically conductive glazing which does not suffer from the problems described and which has enhanced transparency and improved optics compared to known prior art electrically conductive glazings.

Accordingly, the present invention provides a glazing comprising:

a pane of glazing material, and

a substantially continuous area of transparent, electrically conductive material printed using an electrically conductive ink onto a surface of the pane,

wherein the ink is of a composition comprising a fluid vehicle and two different metal species, said fluid vehicle being driven off in a high-temperature post-printing step, and the conductive material is capable of functioning as one or more of the following:

a) a heating element for heating an area of the glazing;

b) an alarm sensor for detecting when the structural integrity of the glazing has been compromised;

c) a proximity sensor for detecting an approach to, or contact with, a surface of the glazing;

d) an electrical connection to an electrical device associated with the glazing.

By “a substantially continuous area” it is meant that the area is of a uniform thickness/depth off the surface of the pane (subject to printing tolerances), rather than being formed from discrete droplets (which may or may not merge to some extent).

Provision of a transparent material as an electrically conductive element in a glazing in this manner appears to mitigate the problems with transparency and optics associated with prior art glazings. This means that such an electrically conductive glazing is suitable for use in any desired aperture, where previously the problems with wired, coated and silver-ink-printed glazings often meant that compromises in terms of transparency, optics and feasible functionality had to be made.

The pane of glazing material may be a pane of glass, preferably soda-lime-silica glass which may be clear or body-tinted, or it may be a pane of a rigid plastics material such as polycarbonate. Typically a pane of glazing material is used in a thickness between 1 and 10 mm, preferably between 1.5 and 6 mm. Furthermore the pane may be flat or it may have some degree of curvature.

After being printed onto the surface of the pane, the electrically conductive ink may be subsequently cured and/or dried as necessary. Curing may be achieved directing a high-temperature (e.g. greater than 400° C., preferably greater than 500° C.) infrared radiation source at the printed glazing and drying may be achieved by baking the glazing in a hot (for example 650° C.) oven. One or both of these steps may be necessary to achieve crystallisation of the ink and thus conductivity.

Any suitable transparent conductive ink may be used to print the transparent conductive material in the present invention, however the most preferably choice is an ink containing indium and tin species for forming an indium-tin-oxide (ITO) coating. It has excellent electrical conductivity and transparency, and is a material that is relatively easy to work with. Other materials having similar properties can also be used however, such as an antimony-based ink, e.g. antimony-tin-oxide (ATO).

The conductive ink may be printed in a thickness which is, subsequent to being cured and/or dried around 300 nm, preferably 10-250 nm and more preferably 50-100 nm, and it may consequently have a sheet resistance of less than 500 Ω/square, preferably in the range 200-350 Ω/square. Of course, the thicker the layer of conductive ink that is printed, the lower its sheet resistance, however this must be balanced against the apparent tendency for the layer to crack during curing/drying as its thickness is increased.

The area of electrically conductive material may be printed using any known printing technique including screen printing, extrusion, pad printing, roller printing, gravure printing, ink-jet printing, to name but a few. To enable accurate printing, the electrically conductive ink is preferably a relatively viscous material (having a viscosity greater than 5,000 mPa·s), in which the two metal species may be suspended, dissolved, emulsified, etc. in the fluid vehicle (e.g. a solvent) which is subsequently driven off as the conductive layer is cured/dried. In which case, the conductive layer is preferably “wet-printed” in a thickness up to around 50 μm (typically 20-30 μm); the thickness then being reduced as described above as the layer is cured/dried.

As a measure of the visible light transmittance of the electrically conductive material, a glazing comprising a ply of 2.1 mm thick clear float glass preferably has a visible light transmittance in the region of the electrically conductive layer (measured with CIE Illuminant A) of greater than 80%, preferably 85% to ensure sufficient visibility, even for automotive applications. Furthermore the colour of the glazing in this region is preferably as neutral as possible, and may be defined using the CIELAB colour co-ordinates using a D65 Illuminant and 2° observer angle as follows: −2.0≦a*≦0 and 0≦b*≦2.0.

As for the area over which the conductive material is printed, it may be in the form of one or more lines (meandering and/or straight) and/or one or more patches. Printing enables accurate, detailed printed shapes to be achieved that would not necessarily have been possible with prior art glazings.

When designed to function as a heating element to de-mist or de-ice the glazing, the conductive material is preferably printed as a continuous film over a portion of the glazing, so that substantially the entire glazing (or at least that part which is required to be transparent) can be heated. This may be useful to remove condensation and/or frost that may have developed on a surface of the glazing. The design may also include a printed connection area for attachment of an electrical connector to provide power to the heating array. Advantageously, the film and connection area may be integrally printed.

When designed to function as an alarm sensor, the conductive material may be printed as a continuous line adjacent the periphery of the glazing, to form a closed electrical circuit.

Any breakage of the glazing (including hairline fractures) leading to interruption of the circuit may be programmed to trigger an alarm. Of course other alarm sensor patterns are also possible, such as a grid over the surface of the glazing. The transparency of the electrically conductive material makes such possible.

When designed to function as a proximity sensor, the conductive material is preferably a capacitive sensing plate and may be capable of signalling the presence of a moisture droplet (thereby functioning as a rain sensor) or a human digit (thereby functioning as a touch sensor). The proximity sensor may be incorporated into a capacitive circuit in the same way as any other capacitive sensor plate would be in the art. The surface area of the proximity sensor may vary greatly—it may extend over substantially the entire surface of the glazing or it may extend over one or more smaller areas.

When designed to function as an electrical connection, the conductive material may be printed as one or more fine lines and/or a patch on the glazing between a locating point for the electrical device and a connection point for an electrical connector. The locating point and/or the connection point may be configured as loops to enable inductive coupling of electrical power to the electrical device via the pane of glazing material. The electrical device may advantageously be a lighting device, for example comprising one or more light emitting diodes.

Alternatively the electrical device may be an electrochromic mirror or a camera, such as a lane-departure camera or collision avoidance camera, which may be especially useful devices if the glazing is an automotive glazing. The operation of such a camera may also benefit from the heating effect of the electrically conductive material to de-mist or de-ice the patch of glazing through with it receives/transmits data. Because printing is such a versatile and controllable deposition technique, any number of randomly (or orderly) arranged locating points may be provided on the glazing, thereby increasing design freedom in placement of electrical devices, such as lighting devices, electrochromic mirrors and cameras.

When designed to function as an antenna, the conductive material is preferably printed in a linear configuration so as to enable reception and/or transmission of electromagnetic radiation. There are many antenna designs known in the art, any of which can be used in the present invention.

A glazing according to the invention may advantageously be in the form of a laminate, having a further pane of glazing material joined to the first pane of glazing material by a ply of interlayer material. The electrically conductive material may be printed on an inner surface of the laminate, which means that it may be printed on surface two of the glazing (on the inner surface of the outer pane), on surface three of the glazing (on the inner surface of the inner pane) or on a surface of the ply of interlayer material. This may be necessary to protect the electrically conductive material itself from environmental damage and, for example when it is designed as a heating element, to prevent persons from touching the material and potentially burning themselves. However it is possible to print the conductive material on surface four of the glazing (the outer surface of the inner pane, i.e. the innermost surface of the glazing), especially when for example an electrical device is located over the print to cover and protect it.

The ply of interlayer material may be a flexible plastics material, which may be clear or body-tinted. Suitable interlayer materials include polyvinyl chloride (“PVC”), polyurethane (“PU”), ethyl vinyl acetate (“EVA”), polyethylene terephthalate (“PET”) and polyvinyl butyral (“PVB”), the most common choice for lamination being PVB, typically used in 0.76 mm thickness, although 0.38 mm thickness is also used.

A glazing according to the invention may be a vehicle glazing or a glazing for use in a building. When used in a vehicle, it may be used as a windscreen and/or a backlight (rear window) and/or a sidelight (side window), with any or all of the functions described herein.

For a better understanding, the present invention will now be more particularly described by way of non-limiting example with reference to, and as shown in, the accompanying schematic drawings (not to scale) wherein:

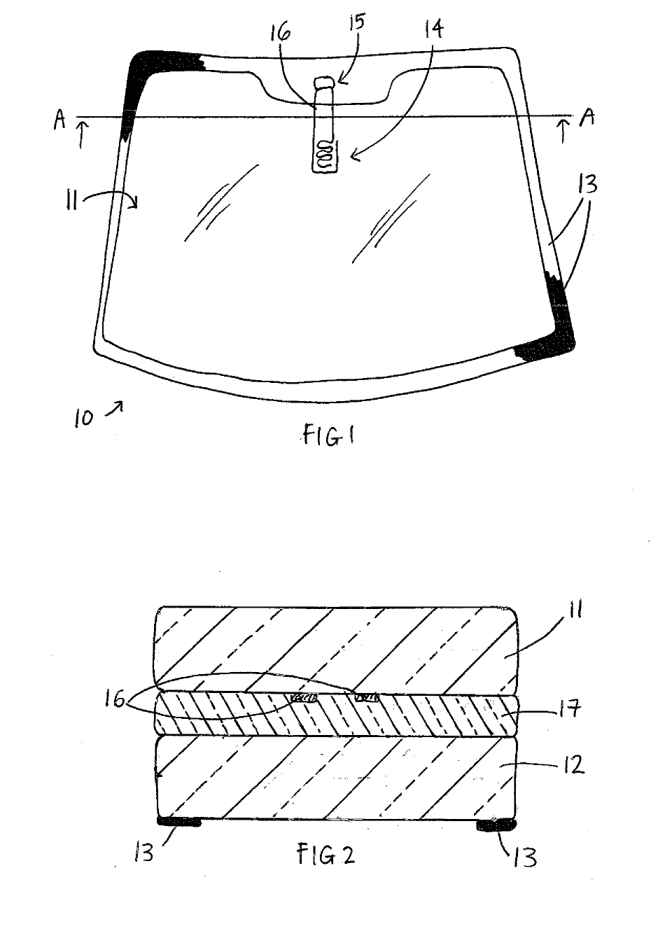

FIG. 1 is a plan view of a glazing according to a first embodiment of the invention;

FIG. 2 is a cross-section viewed along line A-A of FIG. 1;

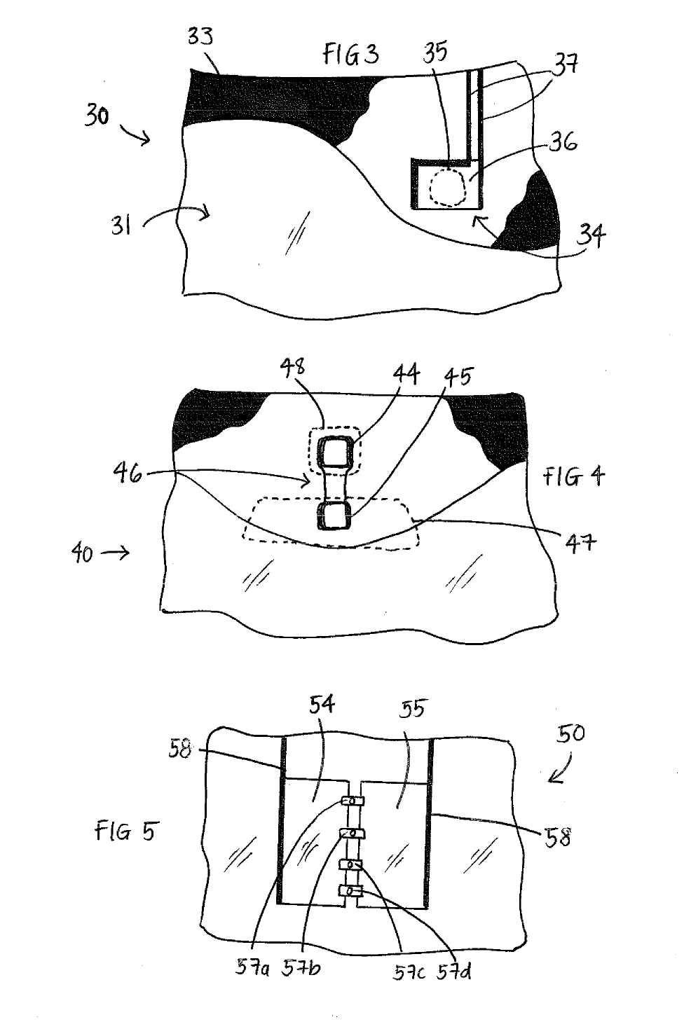

FIG. 3 is a sectional plan view of a glazing according to a second embodiment of the invention;

FIG. 4 is a sectional plan view of a glazing according to a third embodiment of the invention; and

FIG. 5 is a sectional plan view of a glazing according to a fourth embodiment of the invention.

FIG. 1 shows a laminated glazing, in the form of a vehicle windscreen 10, comprising an outer pane of glazing material, in the form of a pane of soda-lime-silica glass 11, and an area of transparent electrically conductive material in the form of screen printed ITO ink 16. ITO ink 16 is screen printed in the form of a capacitive rain sensor 14, which is mostly located in the vision area of the glazing, and an inductive coupling coil 15, which is hidden from view. Around the periphery of windscreen 10 there is a band of opaque ink (typically a black enamel), in the form of an obscuration band 13. Obscuration band 13 is there to disguise and protect the sealant (not shown) that is used to fix the window into a vehicle (not shown), and also to hide inductive coupling coil 15.

FIG. 2 provides more detail about the construction of windscreen 10 in that it further comprises inner pane of glazing material, also in the form of a pane of soda-lime-silica glass 12, and an interlayer, in the form of a ply of clear PVB 17. Ink 16 is printed on the inner surface of outer pane of glass 11, to enable capacitive detection of the presence of raindrops on the outer surface of outer pane of glass 11. However it could alternatively be printed on the adjacent surface of interlayer ply 17.

FIG. 3 illustrates a section of an alternative glazing 30 which comprises an outer pane of glazing material, in the form of a pane of clear soda-lime-silica glass 31, an inner pane of glazing material, also in the form of a pane of soda-lime-silica glass (not shown) and an area of transparent electrically conductive material in the form of ITO ink 36, printed in the form of a heating element 34, for heating that area of the glazing.

Located on surface four of the glazing (the innermost surface of the glazing) there is provided an electrical device in the form of a camera 35 (shown schematically in outline) such as a collision avoidance camera. An electrical connection 37 is provided to heating element 34 in the form of tracks of ink and corresponding busbars, to provide electrical energy to heating element 34 to enable it to perform its heating function. Around the periphery of glazing 30 there is a band of opaque ink (typically a black enamel), in the form of an obscuration band 33, which disguises the fittings around camera 35.

FIG. 4 shows a section of a further alternative glazing 40 which is similar in construction to glazings 10, 30 except that the area of transparent electrically conductive material, in the form of ITO ink 46, is printed in the form of two inductive coupling loops 44, 45. Said loops 44, 45 provide an electrical connection to an electrical device, in the form of an electrochromic rear-view mirror 47 (shown schematically in outline) from a power source 48 (also shown schematically in outline), which is located on surface four of the glazing. Power source 48 inductively couples electrical power into loop 44, which transmits the power to loop 45, which then inductively couples the electrical energy into mirror 47.

FIG. 5 illustrates a section of a yet further alternative glazing 50 which is similar in construction to glazings 10, 30, 40 except that the area of transparent electrically conductive material, in the form of ITO ink 56, is printed in the form of two electrically conductive patches 54, 55 for providing an electrical connection to an electrical device, in the form of an array of four light emitting diodes 57a, 57b, 57c, 57d. The electrical connection is provided from a power source via conductive tracks and busbars 58, all of which is located between the outer and inner panes of glazing material.

To demonstrate the transparency and electrical properties of the ITO printed areas in the embodiments of the invention described above, four samples measuring 180 mm² of 2.1 mm thick clear soda-lime-silica float glass of the composition described below were screen printed with “wet” ITO ink forming a substantially continuous area. The composition of the glass used is approximately 72% SiO₂, 1% Al₂O₃, 0.1% Fe₂O₃, 13.5% Na₂O, 0.6% K₂O, 8.5% CaO, 4% MgO and 0.2% SO₃. The ink, currently available as DX-420 from Sumitomo Metal Mining Co., Ltd., Functional Coating Materials Business Unit, 11-3,5-chome, Shinbashi, Minato-ku, Tokyo, 105-8716 Japan, was then dried by baking each of the samples in an oven in an atmosphere of air at 650° C. for 8 minutes. Once cooled, the visible light transmission (LT (Illuminant A)), a* and b* colour co-ordinates in transmission (Illuminant D65, 2° observer angle) and non-contact sheet resistance were measured for each of the samples/prints. The results are summarised in the table below:

| | Wet ITO | | | | Sheet |
|---|---|---|---|---|---|
| | Thickness | LT_{A} | | | Resistance |
| Example | (μm) | (%) | a* | b* | (Ω/square) |
| 1 | 12 | 87.16 | −0.68 | 0.42 | 220 |
| 2 | 18 | 88.89 | −1.16 | 0.17 | 340 |
| 3 | 10 | 87.91 | −0.74 | 0.6 | 240 |
| 4 | 12 | 87.81 | −0.73 | 0.66 | 300 |

Clearly at these print thicknesses, the visible light transmission of each of the samples is greater than 80%, and indeed is greater than 85%, and the colour in transmission of each sample is neutral, thus ensuring that the prints are substantially invisible to the human eye and more aesthetically pleasing than prior art glazings.

1. A glazing comprising
a pane of glazing material, and
a substantially continuous area of transparent, electrically conductive material printed using an electrically conductive ink onto a surface of the pane,
wherein the ink is of a composition comprising a fluid vehicle and two different metal species, said fluid being driven off in a high-temperature post-printing step, and the conductive material is capable of functioning as one or more of the following:
a) a heating element for heating an area of the glazing;
b) an alarm sensor for detecting when the structural integrity of the glazing has been compromised;
c) a proximity sensor for detecting an approach to, or contact with, a surface of the glazing;
d) an electrical connection to an electrical device associated with the glazing;
e) an antenna for receiving and/or transmitting electromagnetic radiation.

2. A glazing as claimed in claim 1 wherein the electrically conductive ink is cured and/or dried subsequent to being printed onto the surface of the pane.

3. A glazing as claimed in claim 2 wherein the electrically conductive ink is an ink containing indium and tin species for forming an indium-tin-oxide (ITO) coating, or antimony and tin species for forming an antimony-tin-oxide (ATO) coating.

4. A glazing as claimed in claim 2 wherein the thickness of the layer of electrically conductive material is, subsequent to being cured and/or dried, around 300 nm.

5. A glazing as claimed in claim 2 wherein the electrically conductive material has a sheet resistance of less than 500 Ω/square.

6. A glazing as claimed in claim 1 wherein the area of electrically conductive material is printed using any one or more of the following techniques: screen printing, extrusion, pad printing, roller printing, gravure printing, ink-jet printing.

7. A glazing as claimed in claim 1 wherein the electrically conductive material is “wet-printed” in a thickness up to around 50 μm.

8. A glazing as claimed in claim 1 having, when the pane of glazing material is a pane of 2.1 mm thick clear float glass, in the region of the electrically conductive material, a visible light transmittance of greater than 80% (measured with CIE Illuminant A).

9. A glazing as claimed in claim 1 wherein, when designed to function as a heating element, the conductive material is printed as an array of fine lines or a patch over a portion of the glazing.

10. A glazing as claimed in claim 1 wherein, when designed to function as an alarm sensor, the conductive material is printed as a continuous line adjacent the periphery of the glazing.

11. A glazing as claimed in claim 1 wherein, when designed to function as a proximity sensor, the conductive material is a capacitive sensing plate and is capable of signalling the presence of a moisture droplet (as a rain sensor) or a human digit (as a touch sensor).

12. A glazing as claimed in claim 1 wherein, when designed to function as an electrical connection, the conductive material is printed as one or more fine lines and/or a patch on the glazing between a locating point for the electrical device and a connection point for an electrical connector.

13. A glazing as claimed in claim 1 wherein the electrical device is a lighting device or a camera.

14. A glazing as claimed in claim 1 wherein, when designed to function as an antenna, the conductive material is printed in a linear configuration so as to receive and/or transmit radio and/or TV frequency radiation.

15. A glazing as claimed in claim 1 wherein the glazing is a laminate, having a further pane of glazing material joined to the first pane of glazing material by a ply of interlayer material.

16. A glazing as claimed in claim 15 wherein the electrically conductive material is printed onto an inner surface of the laminate.

17. A glazing as claimed in claim 1 wherein the glazing is a vehicle glazing.
